(19) United States
(12) Patent Application Publication
(10) Pub. No.: US 2023/0335542 A1
(43) Pub. Date: Oct. 19, 2023

(54) DISPLAY DEVICE AND METHOD FOR MANUFACTURING DISPLAY DEVICE

(71) Applicant: KYOCERA Corporation, Kyoto-si, Kyoto (JP)

(72) Inventor: Masaya TAMAKI, Yokohama-shi, Kanagawa (JP)

(21) Appl. No.: 18/025,566

(22) PCT Filed: Sep. 2, 2021
(86) PCT No.: PCT/JP2021/032364

§ 371 Date: Mar. 9, 2023

(30) Foreign Application Priority Data
Sep. 14, 2020 (JP) 2020-153783

(51) Int. Cl. H01L 25/16

(52) U.S. Cl. CPC H01L 25/167

(57) ABSTRACT

A display device includes a cavity structure including a display surface and a cavity in the display surface, and a light emitter in the cavity. The cavity includes a bottom surface and a side wall. The side wall is conductive or semiconductive. A height of the side wall is greater than or equal to three times a height of the light emitter.

### TECHNICAL FIELD

The present disclosure relates to a display device including a self-luminous light emitter such as a light-emitting diode (LED), and a method for manufacturing the display device.

### BACKGROUND OF INVENTION

A known display device is described in, for example, Patent Literature 1.

### CITATION LIST

### Patent Literature

Patent Literature 1: Japanese Unexamined Patent Application Publication No. 2013-37138

### SUMMARY

In an aspect of the present disclosure, a display device includes a cavity structure including a display surface and a cavity in the display surface, and a light emitter in the cavity. The cavity includes a bottom surface and a side wall. The side wall is conductive or semiconductive. A height of the side wall is greater than or equal to three times a height of the light emitter.

In another aspect of the present disclosure, a first method for manufacturing a display device includes preparing a substrate to include a surface having a portion corresponding to a bottom surface of a cavity to accommodate a light emitter, placing a light emitter on the bottom surface, and placing a side wall of the cavity on a portion of the surface other than the portion corresponding to the bottom surface. The side wall contains a conductive material or a semiconductive material. A height of the side wall is greater than or equal to three times a height of the light emitter.

In still another aspect of the present disclosure, a second method for manufacturing a display device includes preparing a first transparent substrate including a first surface having a placement portion on which a light emitter is placeable, and a second transparent substrate including a second surface to face the first surface and including a portion corresponding to a bottom surface of a cavity to accommodate the light emitter at a position to face the placement portion, placing the light emitter on the placement portion, and placing a side wall of the cavity on a portion of the second surface other than the portion corresponding to the bottom surface. The side wall contains a conductive material or a semiconductive material. A height of the side wall is greater than or equal to three times a height of the light emitter.

### BRIEF DESCRIPTION OF THE DRAWINGS

The objects, features, and advantages of the present disclosure will become more apparent from the following detailed description and the drawings.

FIG. 1 is a schematic partial plan view of a display device according to an embodiment of the present disclosure.

FIG. 2 is a partial cross-sectional view taken along line A1-A2 in FIG. 1.

FIG. 3 is a schematic partial cross-sectional view of a display device according to another embodiment of the present disclosure.

FIG. 4 is a schematic partial cross-sectional view of a display device according to another embodiment of the present disclosure.

FIG. 5 is a schematic partial cross-sectional view of a display device according to another embodiment of the present disclosure.

FIG. 6 is a schematic partial cross-sectional view of a display device according to another embodiment of the present disclosure.

FIG. 7 is a schematic partial cross-sectional view of a display device according to another embodiment of the present disclosure.

FIG. 8 is a schematic partial cross-sectional view of a display device according to another embodiment of the present disclosure.

FIG. 9 is a flowchart of a method for manufacturing the display device according to an embodiment of the present disclosure.

FIG. 10 is a schematic partial cross-sectional view of an example double-sided display device.

FIG. 11 is a flowchart of a method for manufacturing the display device according to an embodiment of the present disclosure.

### DESCRIPTION OF EMBODIMENTS

The structure that forms the basis of a display device according to one or more embodiments of the present disclosure will now be described. Various display devices with multiple light-emitting portions including self-luminous light emitters such as light-emitting diodes (LEDs) have been developed. Patent Literature 1 describes a display device including multiple light-emitting portions arranged on a substrate. Each light-emitting portion includes a light emitter and a resin partition surrounding the light emitter.

In such a known display device, the substrate easily accumulates static electricity and may cause electrostatic discharge damage to light-emitting layers in the light emitters. While the light emitters are being driven, the known display device may have low dissipation of heat from the light emitters outside the display device. The light emitters may thus have lower light emission efficiency due to heat, lowering the luminance of display images.

Light emitters have recently been smaller and more power-saving in response to increased definition of display images. To avoid lowering the image quality (e.g., luminance or contrast) of display images, the display device is to increase the directivity and the output efficiency of light emitted from its light-emitting portions.

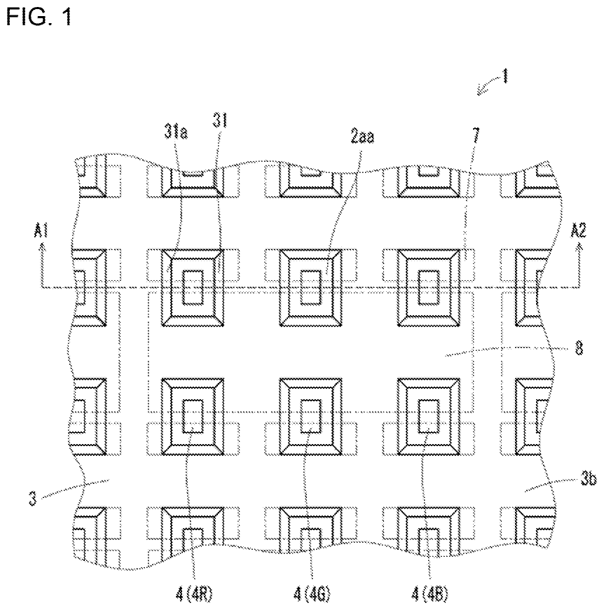

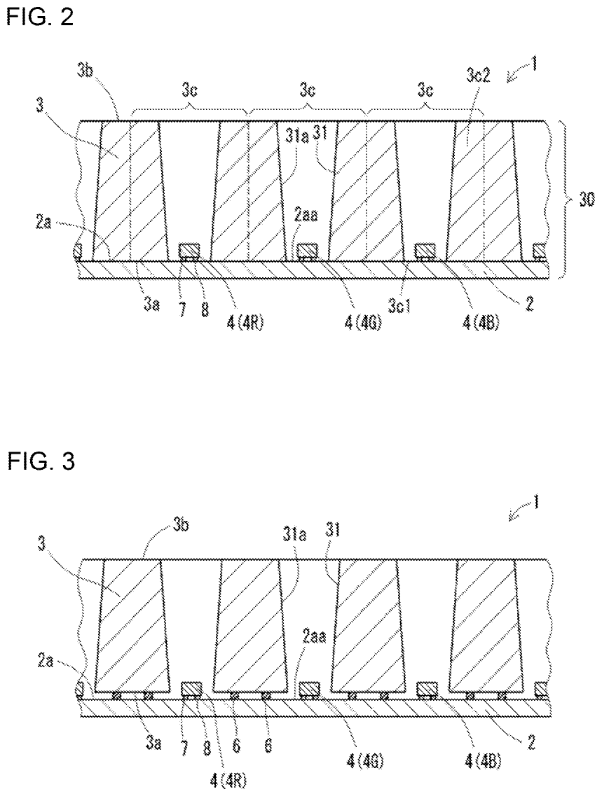

FIG. 1 is a schematic partial plan view of a display device according to an embodiment of the present disclosure. FIG. 2 is a partial cross-sectional view taken along line A1-A2 in FIG. 1. FIGS. 3 to 8 are each a schematic cross-sectional view of a display device according to another embodiment of the present disclosure. The cross-sectional views of FIGS. 3 to 8 correspond to the cross-sectional view of FIG. 2.

As illustrated in FIG. 2, in one or more embodiments of the present disclosure, a display device 1 includes a cavity structure 30 and a light emitter 4. The cavity structure 30 comprises a display surface 3b and a cavity 3c in the display surface 3b. The light emitter 4 is in the cavity 3c. The cavity 3c includes a bottom surface 3c1 and a side wall 3c2 that is conductive or semiconductive. In other words, the cavity 3c is defined by the bottom surface 3c1 and the side wall 3c2 that is conductive or semiconductive. In the display device 1, a height of the side wall 3c2 is greater than or equal to three times the height of the light emitter 4. The above display surface 3b is the image display surface of the display device 1 to be viewed externally by a viewer. The cavity 3c is open in the display surface 3b. The light emitter 4 may be mounted on the bottom surface 3c1. The height of the side wall 3c2 and the height of light emitter 4 herein each refer to the height relative to the bottom surface 3c1. As described later, the bottom surface 3c1 is included in a first surface 2a of a first substrate 2, and the cavity 3c is defined by a through-hole 31 in a second substrate 3.

The above display device 1 produces the effects described below. The side wall 3c2 of the cavity 3c may serve as a static dissipative portion to dissipate static electricity. When an insulating substrate, which easily accumulates static electricity, is used as the first substrate 2 including the bottom surface 3c1, the first substrate 2 with the above structure accumulates less static electricity and reduces electrostatic discharge damage to the light-emitting layer in the light emitter 4. The light emitter 4 may include a cathode terminal electrically connected to the side wall 3c2. In this case, the side wall 3c2 with a large surface area and a large volume can serve as a stable cathode potential portion. This stabilizes the characteristics of the light emitter 4 and facilitates control of, for example, the luminance. The side wall 3c2 of the cavity 3c may be made of a metal material or an alloy material, which is conductive, or made of a dense crystalline material such as silicon, which is semiconductive. The side wall 3c2 made of such materials is highly thermally conductive. This allows effective dissipation of heat from the light emitter 4 outside. The display device thus avoids lowering the light emission efficiency of the light emitter 4 and displays high-luminance images. The side wall 3c2 defining the cavity 3c has a height greater than or equal to three times the height of the light emitter 4. The cavity 3c is thus deep and further increases the light directivity and the light output efficiency. The display device thus avoids lowering the image quality (e.g., luminance or contrast) of display images when the light emitter 4 is smaller and more power-saving in response to increased definition of display images.

The height of the side wall 3c2 is greater than or equal to three times the height of the light emitter 4. The cavity 3c with the side wall 3c2 thus defines the deep through-hole 31. This allows light radiating from the light emitter 4 to be reflected on an inner surface 31a of the through-hole 31 at least once, or for example, multiple times. This allows substantially collimated light to be emitted through the through-hole 31. The display device 1 thus emits light with increased directivity. For example, the light emitter 4 can radiate light with maximum intensity in a direction at an angle of about 20 to 50° to a direction perpendicular to the display surface 3b. In this case, the inner surface 31a of the through-hole 31 can reflect light with maximum intensity radiating in the direction multiple times, or for example, about two to five times.

To allow light radiating from the light emitter 4 with maximum intensity in that direction to be reflected on the inner surface 31a of the through-hole 31 multiple times, the side wall 3c2 may have a height about 3 to 20 times inclusive, or about 5 to 10 times inclusive, the height of the light emitter 4.

The light emitter 4 may have, but is not limited to, a height of about 2 to 10 μm. The side wall 3c2 may have, but is not limited to, a height of about 30 to 300 μm.

The display device 1 will now be described in detail. As illustrated in, for example, FIG. 2, the display device 1 includes the first substrate 2, the second substrate 3, and the light emitter 4. The first substrate 2 may be insulating. The first substrate 2 may be referred to as a substrate. The first substrate 2 made of a transparent material may be referred to as a first transparent substrate. The second substrate 3 includes the through-hole 31 extending through the second substrate 3 in the thickness direction to guide light radiating from the light emitter 4. The second substrate 3 may be conductive or semiconductive. The second substrate 3 may be referred to as a cavity component. The second substrate 3 made of a transparent material may be referred as a second transparent substrate. The light emitter 4 is located on a portion 2aa of the first substrate 2 exposed through the through-hole 31. The portion 2aa may be referred to as an element-mounting portion 2aa. The element-mounting portion 2aa corresponds to the bottom surface 3c1 of the cavity 3c. In other words, the cavity structure 30 comprises the first substrate 2 and the second substrate 3. The first substrate 2 includes the first surface 2a. The first surface 2a includes the bottom surface 3c1. The second substrate 3 is on the first surface 2a. The second substrate 3 includes a second surface 3a facing the first surface 2a, and a third surface 3b opposite to the second surface 3a. The third surface 3b corresponds to the display surface 3b of the cavity structure 30. The second substrate 3 includes the through-hole 31 extending through the second substrate 3 from the second surface 3a to the third surface 3b. The through-hole 31 allows the bottom surface 3c1 to be exposed on the first substrate 2. The second substrate 3 defines the side wall 3c2 of the cavity 3c. The light emitter 4 is located on the bottom surface 3c1 exposed through the through-hole 31.

The first substrate 2 may include a light-reflective layer on the first surface 2a. This allows light radiating from the light emitter 4 to the first surface 2a of the first substrate 2 to be reflected above the through-hole 31, allowing a higher utilization of the light. The light-reflective layer may be made of, for example, a metal material or an alloy material with a high reflectance of visible light. Examples of the metal material used for the light-reflective layer include aluminum (Al), silver (Ag), gold (Au), chromium (Cr), nickel (Ni), platinum (Pt), and tin (Sn). Examples of the alloy material include duralumin, which is an aluminum alloy mainly containing aluminum (an Al—Cu alloy, an Al—Cu—Mg alloy, or an Al—Zn—Mg—Cu alloy). These materials have a light reflectance of about 90 to 95% for aluminum, about 93% for silver, about 60 to 70% for gold, about 60 to 70% for chromium, about 60 to 70% for nickel, about 60 to 70% for platinum, about 60 to 70% for tin, and about 80 to 85% for an aluminum alloy. The light-reflective layer of, for example, aluminum, silver, gold, or an aluminum alloy thus effectively increases the utilization of light.

For the first substrate 2 with a drive circuit including a thin-film transistor (TFT), the light-reflective layer may be located nearer the light emitter 4 than the drive circuit. In this case, the light-reflective layer also serves as a light shield layer for a channel of the TFT, and reduces malfunction of the drive circuit caused by a light leakage current flowing through the channel. For the first substrate 2 including the drive circuit on the first surface 2a, the light-reflective layer may be located on the drive circuit with an insulating layer in between. The insulating layer may be made of, for example, silicon oxide (SiO₂) or silicon nitride (Si₃N₄).

As the light shield layer for the channel of the TFT, the light-reflective layer may be replaced with a light-absorbing layer. The light-absorbing layer may be formed by, for example, applying a photo-curing or a thermosetting resin material containing a light-absorbing material to the first surface 2a and curing the material. Examples of the resin material include a silicone resin, an epoxy resin, an acrylic resin, and a polycarbonate resin. The light-absorbing material may be, for example, an inorganic pigment. Examples of the inorganic pigment may include carbon pigments such as carbon black, nitride pigments such as titanium black, and metal oxide pigments such as Cr—Fe—Co, Cu—Co—Mn (manganese), Fe—Co—Mn, and Fe—Co—Ni—Cr pigments.

As illustrated in, for example, FIG. 3, the display device 1 may include insulators 6 between the first substrate 2 and the second substrate 3. The insulators 6 separate the second substrate 3 from, for example, wiring or a drive circuit located on the first surface 2a of the first substrate 2 and connected to an anode terminal and a cathode terminal of the light emitter 4. This reduces short-circuiting between components such as the wiring and the drive circuit through the second substrate 3. Further, the second substrate 3 can serve as at least one of a static dissipative portion or a cathode potential portion that is electrically independent of, for example, wiring or an electrode as an anode potential portion.

The cavity structure 30 may include one or more cavities 3c. The number of cavities 3c may correspond to the number of light emitters 4. In the display device 1 including multiple light emitters 4, the light emitters 4 may be located in the respective multiple cavities 3c.

The first substrate 2 includes a main surface (hereafter also referred to as the first surface) 2a. The first substrate 2 may be, for example, triangular, square, rectangular, hexagonal, trapezoidal, circular, oval, elliptic, or in any other shape as viewed in plan (in other words, as viewed in a direction perpendicular to the first surface 2a).

The first substrate 2 is made of, for example, a glass material, a ceramic material, a resin material, a metal material, an alloy material, or a semiconductor material. Examples of the glass material used for the first substrate 2 may include borosilicate glass, crystallized glass, quartz, and soda glass. Examples of the ceramic material used for the first substrate 2 may include alumina (Al₂O₃), aluminum nitride (AlN), Si₃N₄, zirconia (ZrO₂), and silicon carbide (SiC). Examples of the resin material used for the first substrate 2 may include an epoxy resin, a polyimide resin, a polyamide resin, an acrylic resin, and a polycarbonate resin.

Examples of the metal material used for the first substrate 2 include Al, titanium (Ti), beryllium (Be), magnesium (Mg) (specifically, high-purity magnesium with a Mg content of 99.95% or higher), zinc (Zn), Sn, copper (Cu), iron (Fe), Cr, Ni, and Ag. Examples of the alloy material used for the first substrate 2 include an iron alloy mainly containing iron (a Fe—Ni alloy, a Fe—Ni alloy with 36% nickel or Invar, a Fe—Ni—Co (cobalt) alloy or Kovar, a Fe—Cr alloy, or a Fe—Cr—Ni alloy), duralumin, which is an aluminum alloy mainly containing aluminum (an Al—Cu alloy, an Al—Cu—Mg alloy, or an Al—Zn—Mg—Cu alloy), a magnesium alloy mainly containing magnesium (a Mg—Al alloy, a Mg—Zn alloy, or a Mg—Al—Zn alloy), titanium boride, and a Cu—Zn alloy. Examples of the semiconductor material used for the first substrate 2 include silicon (Si), germanium (Ge), and gallium arsenide (GaAs).

The first substrate 2 may include a single layer of, for example, the glass material, the ceramic material, the resin material, the metal material, the alloy material, or the semiconductor material described above, or may be a stack of multiple layers of any of these materials. For the first substrate 2 being a stack of multiple layers, the layers may be made of the same or different materials.

As illustrated in, for example, FIG. 2, the second substrate 3 is located on the first surface 2a of the first substrate 2. The second substrate 3 is, for example, a plate or a rectangular member. The second substrate 3 includes the second surface 3a facing the first surface 2a of the first substrate 2, and the third surface 3b opposite to the second surface 3a. The third surface 3b is the display surface of the display device 1 for emitting image light. The second substrate 3 may be, for example, triangular, square, rectangular, hexagonal, trapezoidal, circular, oval, elliptic, or in any other shape as viewed in plan. The first substrate 2 and the second substrate 3 may have the same shape as viewed in plan.

As illustrated in, for example, FIGS. 1 and 2, the second substrate 3 includes the through-hole 31 extending through the second substrate 3 from the second surface 3a to the third surface 3b. The through-hole 31 allows the portion (hereafter also referred to as the element-mounting portion) 2aa of the first substrate 2 to be exposed inside.

The through-hole 31 may be, for example, square, rectangular, circular, oval, elliptic, or in any other shape in cross section parallel to the third surface 3b. As illustrated in, for example, FIG. 1, the through-hole 31 may include the opening in the third surface 3b with an outer edge surrounding the outer edge of the element-mounting portion 2aa as viewed in plan. As illustrated in, for example, FIG. 2, the through-hole 31 may have a section parallel to the third surface 3b being gradually smaller in the direction from the third surface 3b toward the second surface 3a. In other words, the opening area of the through-hole 31 in the cross section parallel to the second surface 3a may gradually increase from the second surface 3a toward the third surface 3b. This structure facilitates output of light radiating from the light emitter 4 outside the display device 1.

The through-hole 31 with the above structure can radiate light outside with the radiant intensity distribution with a highly directional pattern. More specifically, the pattern has a longitudinally elongated shape approximate to a cosine surface (or a paraboloid of revolution), with the direction of radiation with maximum intensity substantially aligned with a normal to the third surface 3b and the bottom surface (the first surface 2a) of the through-hole 31. In other words, the radiant intensity distribution of light radiating outside through the through-hole 31 has a highly directional pattern with a longitudinally elongated shape approximate to a cosine surface, which follows Lambert's cosine law. Under Lambert's cosine law, the radiant intensity of light observed from an ideal diffuse radiator is directly proportional to the cosine of the angle θ (cosθ) between the direction of incident light and a normal to the radiating surface, or the third surface 3b and the bottom surface of the through-hole 31 in the display device 1 according to the present embodiment. The cosine surface herein refers to a radiant intensity distribution pattern of light in the shape of a cosine curve as viewed in a longitudinal section.

The second substrate 3 is conductive or semiconductive. For the second substrate 3 being conductive, the second substrate 3 is made of a metal material or an alloy material. Examples of the metal material used for the second substrate 3 include aluminum, titanium, beryllium, magnesium (specifically, high-purity magnesium with a Mg content of 99.95% or higher), zinc, tin, copper, iron, chromium, nickel, and silver. The metal material used for the second substrate 3 may be an alloy material. Examples of the alloy material used for the second substrate 3 include an iron alloy mainly containing iron (a Fe—Ni alloy, a Fe—Ni—Co alloy, a Fe—Cr alloy, or a Fe—Cr—Ni alloy), duralumin, which is an aluminum alloy mainly containing aluminum (an Al—Cu alloy, an Al—Cu—Mg alloy, or an Al—Zn—Mg—Cu alloy), a magnesium alloy mainly containing magnesium (a Mg—Al alloy, a Mg—Zn alloy, or a Mg—Al—Zn alloy), a copper alloy mainly containing copper (a Cu—Zn alloy, a Cu—Zn—Ni alloy, a Cu—Sn alloy, or a Cu—Sn—Zn alloy), and titanium boride.

For the second substrate 3 being semiconductive, the second substrate 3 is made of a semiconductor material. Examples of the semiconductor material used for the second substrate 3 include silicon, germanium, and gallium arsenide. The semiconductor material may be an impurity semiconductor. The impurity semiconductor is a pure intrinsic semiconductor to which a small amount of impurities (dopant) is added (or doped). The doping element determines whether the impurity semiconductor is classified into a p-type semiconductor including holes (electron holes) as carriers or an n-type semiconductor including electrons as carriers. The semiconductor is determined to be the p-type or the n-type depending on the valence of the impurity element and the valence of the semiconductor substituted with the impurities. For example, silicon with a valence of 4 doped with arsenic or phosphorus with a valence of 5 is an n-type semiconductor. Silicon with a valence of 4 doped with boron or aluminum with a valence of 3 is a p-type semiconductor.

For the second substrate 3 being conductive, the second substrate 3 may have an electrical conductivity of, for example, about 10⁴ to 10⁶ Ω⁻¹ cm⁻¹. For the second substrate 3 being semiconductive, the second substrate 3 may have an electrical conductivity of, for example, about 10⁻¹⁰ to 10² Ω⁻¹ cm⁻¹.

The second substrate 3 may be conductive or semiconductive at its surface alone or at its surface layer alone. The second substrate 3 may include a body and a surface layer. The body may be made of an insulating material, such as a resin material, a ceramic material, or a glass material. The surface layer may be made of any of the above conductive or semiconductive materials. The surface layer may have a thickness of about 0.05 to 100 μm. This facilitates formation of the surface layer as a continuous layer.

The second substrate 3 may include a single layer of the metal material, the alloy material, or the semiconductor material described above, or may be a stack of multiple layers of any of these materials. For the second substrate 3 being a stack of multiple layers, the layers may be made of the same or different materials. The through-hole 31 may be formed by, for example, punching, electroforming (plating), cutting, or laser beam machining. For the second substrate 3 made of a metal material or an alloy material, the through-hole 31 may be formed by, for example, punching or electroforming. For the second substrate 3 made of a semiconductor material, the through-hole 31 may be formed by, for example, photolithography including dry etching.

The second substrate 3 defining the side wall 3c2 may be made of an electrically conductive resin. An electrically conductive resin is a resin material that constantly transfers electrons and has a specific resistance of 10⁶ Ω to 10¹² Ω inclusive at the surface. An electrically conductive resin is thus antistatic. Examples of such electrically conductive resins include an acrylonitrile butadiene styrene copolymer synthetic (ABS) resin, a polyacetal (POM) resin containing a conductive member, and a polyetheretherketone (PEEK) resin containing a conductive member. Examples of the conductive member include conductive particles of Ag, Ni, or Cu, carbon particles, and carbon nanotubes.

As described above, the insulators 6 made of an electrical insulating material may be located between the first surface 2a of the first substrate 2 and the second surface 3a of the second substrate 3. This reduces short-circuiting between components such as electrodes and wiring conductors located on the first surface 2a through the second substrate 3. Examples of the electrical insulating material used for the insulators 6 include SiO₂ and Si₃N₄. The insulators 6 may be located on a part of the second surface 3a of the second substrate 3, or may extend across the second surface 3a. Each insulator 6 may be a layer with a thickness of about 0.5 to 10 μm.

The light emitter 4 is located on the element-mounting portion 2aa of the first substrate 2. The light emitter 4 may be a self-luminous element such as an LED, an organic LED (OLED), or a semiconductor laser diode (LD). In the present embodiment, the light emitter 4 is an LED. The light emitter 4 may be a micro-LED, or may be a vertical LED. The micro-LED mounted on the element-mounting portion 2aa may be rectangular as viewed in plan with each side having a length of about 1 to 100 μm inclusive, or about 5 to 20 μm inclusive. The vertical LED is in the shape of, for example, a rectangular prism or a cylinder, and has an anode terminal and a cathode terminal on the two end faces in the height direction. More specifically, the vertical LED may have the anode terminal as one terminal, the light-emitting layer located on the anode terminal, and the cathode terminal as the other terminal located on the light-emitting layer. For the vertical LED in the shape of a rectangular prism, the end faces of the vertical LED may each have a side with a length of about 1 to 100 μm inclusive, or about 5 to 20 μm inclusive.

The first substrate 2 includes a first electrode (also referred to as an anode electrode) 7 and a second electrode (also referred to as a cathode electrode) 8 located on the element-mounting portion 2aa. In other words, the anode electrode 7 and the cathode electrode 8 are located on the element-mounting portion 2aa of the first surface 2a of the first substrate 2 exposed through the second substrate 3. The anode electrode 7 is electrically connected to the anode terminal (first terminal) of the light emitter 4. The cathode electrode 8 is electrically connected to the cathode terminal (second terminal) of the light emitter. The anode electrode 7 and the cathode electrode 8 may be connected to a drive circuit (not illustrated) for controlling, for example, the emission or non-emission state and the light intensity of the light emitter 4.

As described above, the light emitter 4 may have the first terminal (anode terminal) at a first potential (anode potential) and the second terminal (cathode terminal) at a second potential (cathode potential) different from the first potential. The second substrate 3 may be at the second potential. In this case, the second substrate 3 can serve as at least one of the static dissipative portion or the cathode potential portion that is electrically independent of, for example, the wiring or the electrode as the anode potential portion. The second potential (cathode potential) is lower than the first potential (anode potential) and may be a negative potential (not less than about −5 V and less than 0 V) or a ground potential (0 V).

The drive circuit is located on the first substrate 2. The drive circuit may be located at, for example, a bezel on the first surface 2a of the first substrate 2, on a portion between the light emitters 4, or on the surface opposite to the first surface 2a of the first substrate 2. The drive circuit includes, for example, a TFT and a wiring conductor. The TFT may include, for example, a semiconductor film (or a channel) of amorphous silicon (a-Si) or low-temperature polycrystalline silicon (LTPS), and three terminals that are a gate electrode, a source electrode, and a drain electrode. The TFT serves as a switching element that switches conduction and non-conduction between the source electrode and the drain electrode based on the voltage applied to the gate electrode. The drive circuit may be located on the first substrate 2, or between multiple insulating layers of, for example, silicon oxide or silicon nitride located on the first substrate 2. The drive circuit may be formed using a thin film formation method such as chemical vapor deposition (CVD).

For the light emitter 4 being a micro-LED, the light emitter 4 may have the anode terminal connected to the anode electrode 7 by flip-chip connection, and have the cathode terminal connected to the cathode electrode 8 by flip-chip connection. In this case, the display device 1 may include the insulators 6 described above. This reduces short-circuiting between the second substrate 3 and, for example, wiring located on the first surface 2a of the first substrate 2 and connected to the anode electrode 7 or to the cathode electrode 8. The light emitter 4 may be electrically and mechanically connected to the anode electrode 7 and the cathode electrode 8 by flip-chip connection using a conductive connector, such as an anisotropic conductive film (ACF), a solder ball, a metal bump, or a conductive adhesive. The light emitter 4 may be electrically connected to the anode electrode 7 and the cathode electrode 8 using a conductive connector such as a bonding wire.

For the first substrate 2 made of a metal material, an alloy material, or a semiconductor material, the insulating layer of, for example, silicon oxide or silicon nitride may be located at least on the first surface 2a of the first substrate 2. The light emitter 4 may be located on the insulating layer. This reduces electrical short-circuiting between the anode terminal and the cathode terminal of the light emitter 4.

As described above, the display device 1 may include multiple light emitters 4. In this case, the second substrate 3 may include multiple through-holes 31 extending through the second substrate 3 from the second surface 3a to the third surface 3b. The through-holes 31 allows the corresponding element-mounting portions 2aa of the first substrate 2 to be exposed inside. The light emitters 4 may be located on the corresponding element-mounting portions 2aa. The multiple through-holes 31 may be arranged in a matrix as viewed in plan.

The display device 1 may include multiple pixel units. Each pixel unit may include multiple light emitters 4. The multiple light emitters 4 in each pixel unit may include, for example, a light emitter 4R that emits red light, a light emitter 4G that emits green light, and a light emitter 4B that emits blue light. This allows the display device 1 to display full-color gradation.

Each pixel unit may include, in addition to the light emitters 4R, 4G, and 4B, at least one of the light emitter 4 that emits yellow light or the light emitter 4 that emits white light. This improves the color rendering and color reproduction of the display device 1. Each pixel unit may include, instead of the light emitter 4R that emits red light, the light emitter 4 that emits orange, red-orange, red-violet, or violet light. Each pixel unit may include, instead of the light emitter 4G that emits green light, the light emitter 4 that emits yellow-green light.

In the display device 1 according to the present embodiment, the second substrate 3 is made of a metal material, an alloy material, or a semiconductor material, which has higher thermal conductivity than, for example, a resin material or a ceramic material. The second substrate 3 thus easily conducts heat from the light emitters 4 and easily dissipates heat outside. The display device 1 thus allows the light emitters 4 to have the light emission efficiency less susceptible to their heat and stably displays high-luminance images.

In the display device 1, the second substrate 3 may have a linear expansion coefficient being 0.8 to 2 times inclusive the linear expansion coefficient of the first substrate 2. The first substrate 2 and the second substrate 3 thus have less stress at the connection between them while the light emitters 4 are being driven, and are less likely to be separate from each other. This avoids an increase in thermal resistance on the heat dissipation paths (heat conduction paths) from the light emitters 4 to the second substrate 3, and thus allows effective dissipation of heat from the light emitters 4 outside through the second substrate 3. Further, the light emitters 4 have the light emission efficiency less susceptible to their heat, thus allowing high-luminance images to be displayed.

The materials of the first substrate 2 and the second substrate 3 may be selected as appropriate to cause the linear expansion coefficient of the second substrate 3 to be 0.8 to 2 times inclusive the linear expansion coefficient of the first substrate 2. For the first substrate 2 made of a glass material, for example, the second substrate 3 may be made of an iron alloy such as Invar (a Fe—Ni alloy with 36% nickel) or Kovar, or may be made of a semiconductor material such as silicon, germanium, or gallium arsenide.

For the first substrate 2 made of a glass material as an insulating material, for example, the first substrate 2 has a linear expansion coefficient of 8 to 10 (in 10⁻⁶/K, where K is Kelvin indicating the absolute temperature) at around room temperature (about 20° C.). In this case, the second substrate 3 may be made of a metal material such as Cr with a linear expansion coefficient of 8.2 (10⁻⁶/K), Ti with a linear expansion coefficient of 8.5 (10⁻⁶/K), Fe with a linear expansion coefficient of 12.0 (10⁻⁶/K), Ni with a linear expansion coefficient of 12.8 (10⁻⁶/K), Cu with a linear expansion coefficient of 16.8 (10⁻⁶/K), or Sn with a linear expansion coefficient of 20.0 (10⁻⁶/K). For the second substrate 3 made of an alloy material, the second substrate 3 may be made of, for example, a Fe—Ni—Co alloy or Kovar with a linear expansion coefficient of 5.2 (10⁻⁶/K), a Fe—Ni alloy with a linear expansion coefficient of 6.5 to 13.0 (10⁻⁶/K), stainless steel with a linear expansion coefficient of 10.0 to 17.0 (10⁻⁶/K), or a Cu—Zn alloy with a linear expansion coefficient of 19.0 (10⁻⁶/K).

The linear expansion coefficient of a Fe—Ni alloy varies in accordance with the mass content of Ni. For the mass content of Ni being about 27 to 42 mass %, the linear expansion coefficient is as low as about 1 to 6.5 (10⁻⁶/K). In one or more embodiments, the mass content of Ni in a Fe—Ni alloy may be higher than 0 mass % and not higher than 27 mass %, or not lower than 42 mass % and lower than 100 mass %.

For the first substrate 2 made of a polyamide resin material as an insulating material, the first substrate 2 has a linear expansion coefficient of about 30.0 to 40.0 (10⁻⁶/K) at around room temperature (about 20° C.). In this case, the second substrate 3 may be made of a metal material such as Al with a linear expansion coefficient of 23.0 (10⁻⁶/K), Mg with a linear expansion coefficient of 25.4 (10⁻⁶/K), or Zn with a linear expansion coefficient of 30.2 (10⁻⁶/K). In some embodiments, the second substrate 3 may be made of an alloy material such as an Al—Cu alloy with a linear expansion coefficient of 27.3 (10⁻⁶/K) as duralumin.

For the first substrate 2 made of silicon, which is a semiconductor material easy to etch, the first substrate 2 has a linear expansion coefficient of about 2.4 (10⁻⁶/K) at around room temperature (about 20° C.). In this case, the second substrate 3 may be made of silicon or a Fe—Ni alloy. The Fe—Ni alloy has the linear expansion coefficient varying in accordance with the mass content of Ni. Thus, the mass content of Ni may be about 32 mass % with a linear expansion coefficient of 4.8 (10⁻⁶/K) to 34 mass % with a linear expansion coefficient of 2.0 (10⁻⁶/K), or may be about 37 mass % with a linear expansion coefficient of 2.0 (10⁻⁶/K) to mass % with a linear expansion coefficient of 4.8 (10⁻⁶/K).

The first substrate 2 and the second substrate 3 may have the linear expansion coefficients satisfying the above relationship at the operating temperature of the light emitters 4 of −30 to 85° C.

In the display device 1, the inner surfaces 31a of the through-holes 31 may be light-reflective to reflect light radiating from the light emitters 4. The through-holes 31 allow emission of light outside with higher light output efficiency and thus with higher intensity (luminance). This allows substantially collimated light to be emitted through the through-holes 31. The display device 1 emits light with increased directivity and improves the image quality (e.g., luminance or contrast) of display images. To be light-reflective, the inner surfaces 31a of the through-holes 31 may be mirror-like surfaces with metallic luster, may have a mirror finish, or may be coated with a light-reflective film.

In the display device 1, the second substrate 3 may be thicker than the first substrate 2. The display device 1 with this structure has higher mechanical strength and also includes the deep through-holes 31. This allows light radiating from each light emitter 4 to be reflected on the inner surface 31a of each through-hole 31 at least once. This allows substantially collimated light to be emitted through the through-hole 31. The display device 1 thus emits light with increased directivity. To allow light radiating from each light emitter 4 to be reflected on the inner surface 31a of the through-hole 31 at least once, the display device 1 may have parameters determined as appropriate based on, for example, the intensity distribution of light radiating from the light emitter 4. The parameters may include the thickness of the second substrate 3, the shape of the through-hole 31, and the dimensional ratio between the through-hole 31 and the light emitter 4.

The first substrate 2 may have a thickness of about 0.2 to 2.0 mm. The second substrate 3 may have a thickness of about 1.0 to 3.0 mm. However, the first substrate 2 and the second substrate 3 may have thicknesses not limited to these values. The second substrate 3 may be thinner. For example, the thickness of the second substrate 3 may be about 0.03 to 0.3 mm.

The through-holes 31 in the second substrate 3 may include mirror-like inner surfaces 31a. This allows light radiating from the light emitters 4 to be reflected on the inner surfaces 31a with an increased reflectance and a reduced loss. The display device 1 thus outputs light radiating from the light emitters 4 more efficiently and displays high-luminance images.

The inner surfaces 31a of the through-holes 31 may undergo, for example, electrolytic polishing or chemical polishing to have a mirror finish. The inner surfaces 31a may have a surface roughness Ra of, for example, about 0.01 to 0.1 μm. The inner surfaces 31a may have a reflectance of visible light of, for example, about 85 to 95%.

The third surface 3b of the second substrate 3 may be roughened by, for example, blasting. The roughened third surface 3b has a larger surface area and dissipates heat more easily. The roughened third surface 3b also reflects external light diffusely. The display device 1 thus emits light with less interference with reflected external light, avoiding lowering the image quality.

A display device 1 according to another embodiment of the present disclosure will now be described.

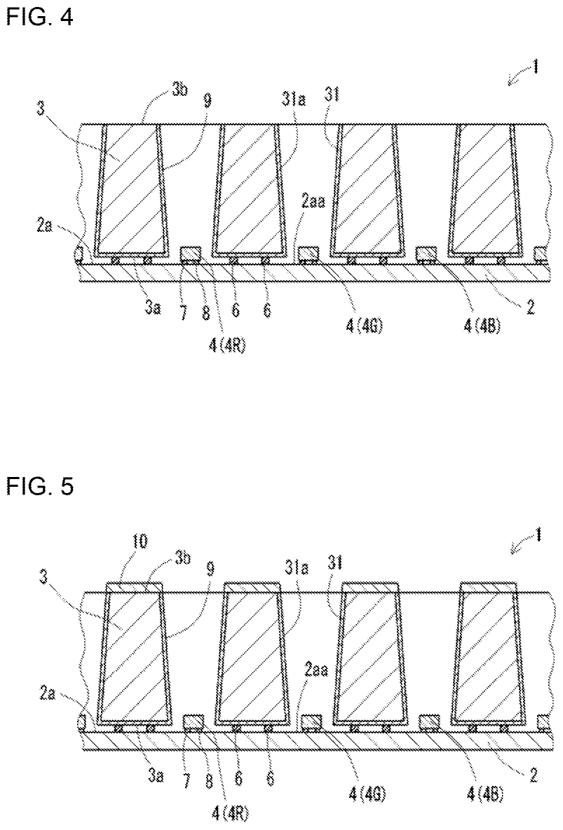

As illustrated in, for example, FIG. 4, the second substrate 3 may include a light-reflective layer 9 on the inner surfaces 31a of the through-holes 31. This allows light radiating from the light emitters 4 to be reflected in the through-holes 31 with an increased reflectance and a reduced loss independently of, for example, the material for the second substrate 3 or the surface roughness Ra of the inner surfaces 31a. The display device 1 thus outputs light radiating from the light emitters 4 more efficiently and displays high-luminance images.

The light-reflective layer 9 may be made of, for example, a metal material or an alloy material with a high reflectance of visible light. Examples of the metal material used for the light-reflective layer 9 include Al, Ag, Au, Cr, Ni, Pt, and Sn. Examples of the alloy material include duralumin, which is an aluminum alloy mainly containing aluminum (an Al—Cu alloy, an Al—Cu—Mg alloy, or an Al—Zn—Mg—Cu alloy). These materials have a light reflectance of about 90 to 95% for aluminum, about 93% for silver, about 60 to 70% for gold, about 60 to 70% for chromium, about 60 to 70% for nickel, about 60 to 70% for platinum, about 60 to 70% for tin, and about 80 to 85% for an aluminum alloy. For the light-reflective layer 9 made of, for example, aluminum, silver, gold, or an aluminum alloy, the display device 1 outputs light radiating from the light emitters 4 more efficiently and displays high-luminance images.

The light-reflective layer 9 may be formed on the inner surfaces 31a of the through-holes 31 using a thin film formation method such as CVD, vapor deposition, or plating, or using a thick film formation method such as firing and solidifying a resin paste containing particles of, for example, aluminum, silver, or gold. The light-reflective layer 9 may be formed on the inner surfaces 31a of the through-holes 31 by joining a film containing, for example, aluminum, silver, gold, or an alloy of any of these metals. A protective film may be located on the outer surface of the light-reflective layer 9 to reduce oxidation of the light-reflective layer 9. Such oxidation may cause a decrease in reflectance.

The light-reflective layer 9 may be located on the inner surfaces 31a of the through-holes 31 alone, or may be located on the inner surfaces 31a of the through-holes 31 and on the second surface 3a of the second substrate 3. When the light radiating from the light emitters 4 partially enters between the first surface 2a of the first substrate 2 and the second surface 3a of the second substrate 3, the light-reflective layer 9 on the second surface 3a of the second substrate 3 can reflect the light and guide the light to the inner surfaces 31a of the through-holes 31.

As illustrated in, for example, FIG. 5, the second substrate 3 may include a light-absorbing layer 10 located on the third surface 3b. The light-absorbing layer 10 absorbs external light incident on the third surface 3b. In the display device 1 according to the present embodiment, the third surface 3b reduces reflection of external light. The display device 1 thus emits image light with less interference with reflected external light, avoiding lowering the image quality.

The light-absorbing layer 10 may include a photo-curing or a thermosetting resin material containing a light-absorbing material. The resin material may be applied to the third surface 3b of the second substrate 3 and cured. Examples of the resin material include a silicone resin, an epoxy resin, an acrylic resin, and a polycarbonate resin. The light-absorbing material may be, for example, an inorganic pigment. Examples of the inorganic pigment may include carbon pigments such as carbon black, nitride pigments such as titanium black, and metal oxide pigments such as Cr—Fe—Co, Cu—Co—Mn, Fe—Co—Mn, and Fe—Co—Ni—Cr pigments.

The light-absorbing layer 10 may include a rough surface that absorbs incident light. For example, the light-absorbing layer 10 may be a black film formed by mixing a black pigment such as carbon black in a base material such as a silicone resin and by roughening the surface of the black film. This structure greatly increases the light-absorbing effect. The rough surface may have an arithmetic mean roughness of about 10 to 50 μm or about 20 to 30 μm. The rough surface may be formed by, for example, transferring.

The third surface 3b of the second substrate 3 may be a light-reflective surface such as a mirror-like surface. The display device 1 with this structure is usable as, for example, a mirror or a rearview mirror for a vehicle such as an automobile when the light emitters 4 are turned off. The display device 1 including multiple light emitters 4 is also usable as an electronic mirror to display images inside and around the vehicle. In this case, a light reflector may be located on the third surface 3b. The light reflector may be a light-reflective layer or a light-reflective film made of, for example, aluminum, an aluminum alloy, or silver. The second substrate 3 may be a metal substrate made of, for example, aluminum, an aluminum alloy, or stainless steel, and the third surface 3b may have a mirror finish.

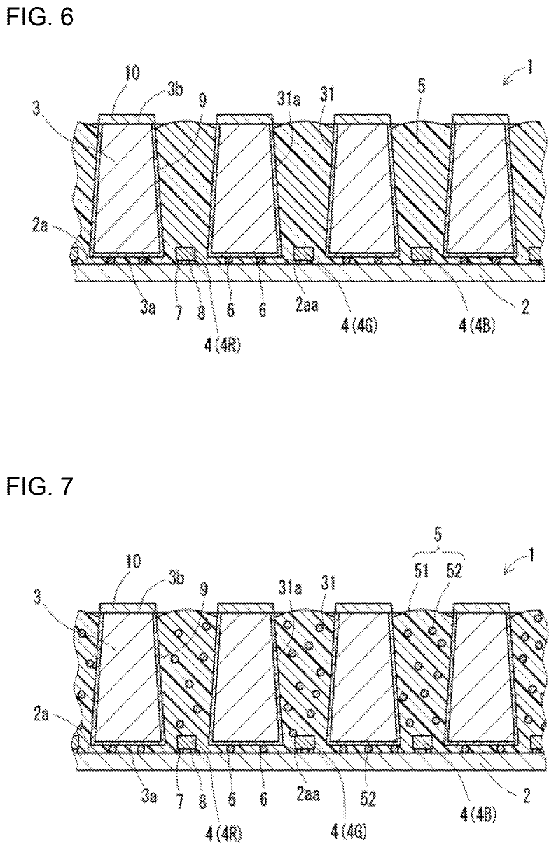

As illustrated in, for example, FIG. 6, the display device 1 may include light-transmissive members 5 located in the through-holes 31. The light-transmissive members 5 are located in the through-holes 31 and seal the light emitters 4. The light-transmissive members 5 fill the through-holes 31, and are in contact with the surfaces of the light emitters 4 and in contact with the inner surfaces 31a of the through-holes 31.

The light-transmissive members 5 are made of, for example, a transparent resin material. Examples of the transparent resin material used for the light-transmissive members 5 include a fluororesin, a silicone resin, an acrylic resin, a polycarbonate resin, and a polymethyl methacrylate resin.

The through-holes 31 filled with the light-transmissive members 5 reduce thermal resistance on the heat dissipation paths (heat conduction paths) from the light emitters 4 to the second substrate 3, as compared with the through-holes 31 filled with gas such as air. In other words, the light-transmissive members 5 made of, for example, the transparent resin material have higher thermal conductivity than the gas such as air. In the present embodiment, the display device 1 thus effectively dissipates heat from the light emitters 4 outside through the light-transmissive members 5 and the second substrate 3. In the present embodiment, the display device 1 thus effectively allows the light emitters 4 to have the light emission efficiency less susceptible to their heat and stably displays high-luminance images.

In the present embodiment, the display device 1 with the light-transmissive members 5 reduces the likelihood of the light emitters 4 being misaligned or separate from the element-mounting portions 2aa after a long use. Thus, in the present embodiment, the display device 1 has higher long-term reliability.

Each light-transmissive member 5 may include a convexly curved surface exposed adjacent to the third surface 3b. In this case, each light-transmissive member 5 includes a convex lens surface exposed adjacent to the third surface 3b and allows light to radiate outside through the through-hole 31 with increased concentration and increased directivity.

As illustrated in, for example, FIG. 7, the light-transmissive members 5 may include dispersed insulating particles 52. For example, each light-transmissive member 5 may include a body 51 made of a transparent resin material, and multiple insulating particles 52 dispersed in the body 51.

Examples of the transparent resin material used for the bodies 51 include a fluororesin, a silicone resin, an acrylic resin, a polycarbonate resin, and a polymethyl methacrylate resin. The insulating particles 52 are made of, for example, a glass material, a ceramic material, or a metal oxide material. Examples of the glass material used for the insulating particles 52 include borosilicate glass, crystallized glass, quartz, and soda glass. Examples of the ceramic material used for the insulating particles 52 include alumina, aluminum nitride, and silicon nitride. Examples of the metal oxide material used for the insulating particles 52 include titanium oxide. The insulating particles 52 may be made of a glass material with a higher refractive index than the bodies 51, or may be made of a ceramic material with a high reflectance of visible light.

For the insulating particles 52 made of a transparent material such as a glass material or a metal oxide material, the insulating particles 52 refract light radiating from the light emitters 4 to be efficiently emitted outside through the through-holes 31. The insulating particles 52 may be light-reflective with a white or a metallic luster color. In this case, the insulating particles 52 can scatter light entering the light-transmissive members 5. The light entering the light-transmissive members 5 can thus be partly scattered and diffused outside the display device. In the present embodiment, the display device 1 reduces the likelihood that external light entering the light-transmissive members 5 is reflected in the through-holes 31 and interferes with light radiating from the light emitters 4. In the present embodiment, the display device 1 thus outputs light with less interference with external light, avoiding lowering the image quality.

The insulating particles 52, which are insulating, also reduce electrical faults such as short-circuiting when being in contact with terminals of the light emitters 4 or in contact with wiring or electrodes on the first surface 2a of the first substrate 2. The insulating particles 52 may be made of a solid material such as a glass material, a ceramic material, or a metal oxide material, which is denser than the bodies 51 of the light-transmissive members 5 made of a transparent resin material. In this case, the insulating particles 52 have higher thermal conductivity than the bodies 51. This improves the overall thermal conductivity of the light-transmissive members 5.

The light-transmissive members 5 may be formed by filling the through-holes 31 with a transparent resin material containing dispersed insulating particles 52 and by curing the material. In manufacturing the display device 1, a transparent resin material containing dispersed insulating particles 52 may be placed and cured between the first surface 2a of the first substrate 2 and the second surface 3a of the second substrate 3 before the first substrate 2 and the second substrate 3 are connected to each other. The insulating particles 52 between the first surface 2a of the first substrate 2 and the second surface 3a of the second substrate 3 reduce short-circuiting between the second substrate 3 and components on the first surface 2a such as the anode electrodes 7, the cathode electrodes 8, or wiring conductors. This structure may eliminate the insulators 6 between the first surface 2a of the first substrate 2 and the second surface 3a of the second substrate 3, as illustrated in, for example, FIG. 7.

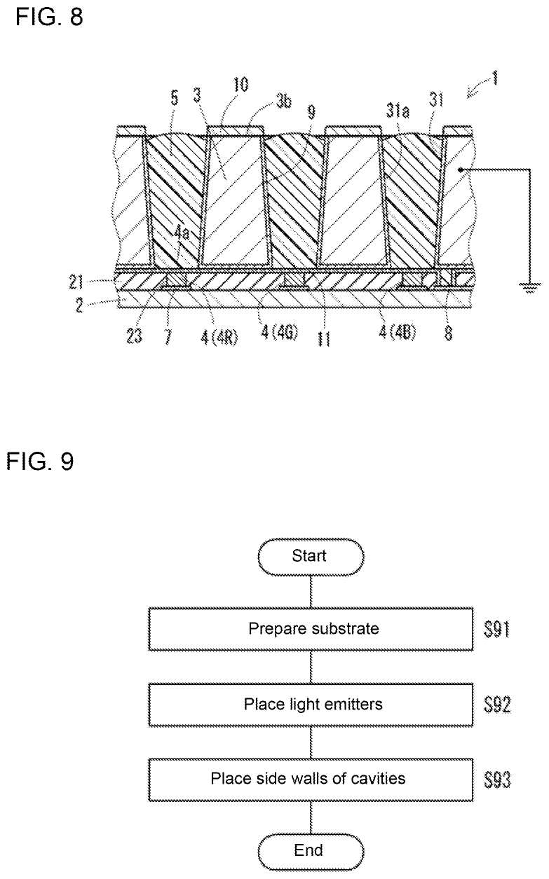

As illustrated in, for example, FIG. 8, an insulating layer 21 may be located on the first substrate 2. The first substrate 2 faces the second substrate 3, and includes the first surface 2a. The insulating layer 21 is nearer the second substrate 3 than the first substrate 2. Examples of the electrical insulating material used for the insulating layer 21 include the glass material, the ceramic material, and the resin material described above.

The insulating layer 21 may include recesses 23 in portions corresponding to the element-mounting portions 2aa. Each light emitter 4 may be located in the corresponding recess 23. For the light emitters 4 being vertical LEDs, the light emitters 4 may be accommodated in the recesses 23 with their light-emitting surfaces 4a facing the openings of the through-holes 31 adjacent to the third surface 3b.

The display device 1 may include a transparent conductor layer 11 located between the first substrate 2 and the second substrate 3 and electrically connected to the second terminals (cathode terminals) of the light emitters 4. The second substrate 3 may be in contact with the transparent conductor layer 11. In this case, the second substrate 3 includes a large area in contact with the transparent conductor layer 11. The second substrate 3 can thus more effectively and stably serve as at least one of the static dissipative portion or the cathode potential portion that is electrically independent of, for example, the wiring or the electrode as the anode potential portion. The transparent conductor layer 11 may be made of, for example, indium tin oxide (ITO) or indium zinc oxide (IZO). As illustrated in, for example, FIG. 8, the transparent conductor layer 11 may cover the light-emitting surfaces 4a of the light emitters 4. The transparent conductor layer 11 may be electrically connected to the second substrate 3 and the cathode terminals of the light emitters 4. The second substrate 3 may be electrically connected to an external ground potential portion. The second substrate 3 may be electrically connected to a power supply at a negative potential (not less than about −5 V and less than 0 V) as the second potential (cathode potential).

The anode electrodes 7 and the cathode electrodes 8 may be located between the insulating layer 21 and the first substrate 2. For the light emitters 4 being vertical LEDs, the anode terminals of the light emitters 4 may be directly connected to the anode electrodes 7. The cathode terminals of the light emitters 4 may be connected to the cathode electrodes 8 through the transparent conductor layer 11. As illustrated in, for example, FIG. 8, the transparent conductor layer 11 may include a portion extending through the insulating layer 21 in the thickness direction and connected to a cathode electrode 8. For the first substrate 2 made of a metal material or a semiconductor material, another insulator layer of, for example, silicon oxide or silicon nitride may be located between the insulating layer 21 and the first substrate 2. The anode electrodes 7 and the cathode electrodes 8 may be located between the other insulating layer and the insulating layer 21. This reduces short-circuiting between the anode electrodes 7 and the cathode electrodes 8 through the first substrate 2.

In the display device 1 according to the present embodiment, the second substrate 3 serves as a heat sink to absorb heat from the light emitters 4 and dissipate the heat outside. The display device 1 thus allows the light emitters 4 to have the light emission efficiency less susceptible to their heat and stably displays high-luminance images. Further, in the display device 1 according to the present embodiment, the second substrate 3 serves as a cathode potential portion (ground potential portion) with a stable potential. This stabilizes the ground potential for the light emitters 4, and thus avoids lowering the image quality of the display device 1.

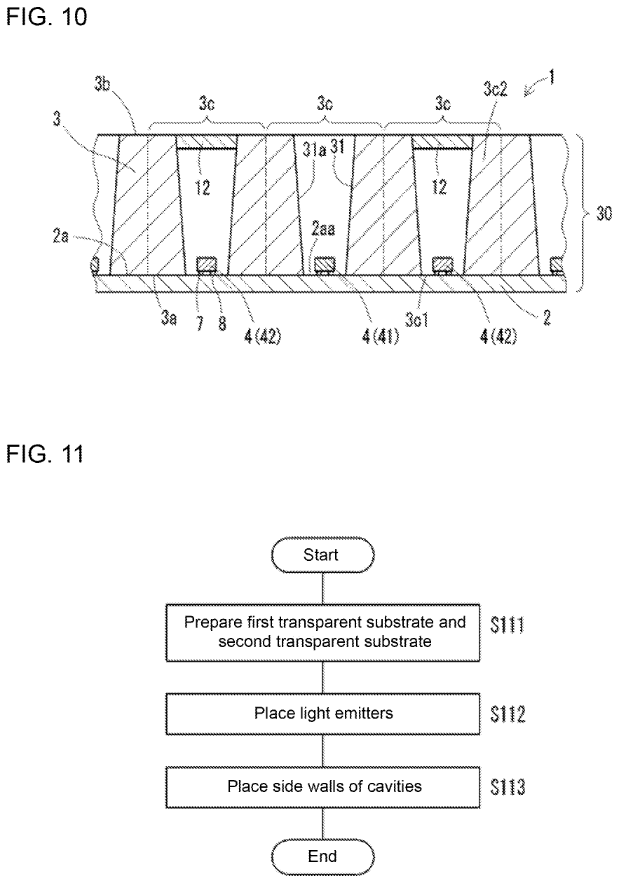

A method for manufacturing the display device according to an embodiment of the present disclosure will now be described. FIG. 9 is a flowchart of a method for manufacturing the display device according to an embodiment of the present disclosure. FIG. 10 is a partial cross-sectional view of an example double-sided display device. FIG. 11 is a flowchart of a method for manufacturing the display device according to an embodiment of the present disclosure. The partial cross-sectional view of FIG. 10 corresponds to the partial cross-sectional views of FIGS. 2 to 8.

As illustrated in, for example, FIG. 9, in an embodiment of the present disclosure, a method for manufacturing the display device (also referred to as a first method for manufacturing the display device) includes processes S91, S92, and S93. The process S91 is the process of preparing the substrate (first substrate) 2 including the surface (first surface 2a) including portions corresponding to the bottom surfaces 3c1 of the cavities 3c to accommodate the light emitters 4. The process S92 is the process of placing the light emitters 4 on the bottom surfaces 3c1. The process S93 is the process of placing the side walls 3c2 of the cavities 3c on portions of the first surface 2a other than the portions corresponding to the bottom surfaces 3c1. The side walls 3c2 are made of a conductive material or a semiconductive material and each have a height greater than or equal to three times the height of each light emitter 4.

The first method for manufacturing the display device produces the effects described below. The display device manufactured with the first method includes the cavities 3c including the side walls 3c2 that can serve as at least one of the static dissipative portion or the cathode potential portion. This stabilizes the characteristics of the light emitters 4 and facilitates control of, for example, the luminance. The side walls 3c2 of the cavities 3c have high thermal conductivity and effectively dissipate heat from the light emitters 4 outside. The display device thus avoids lowering the light emission efficiency of the light emitters 4 and stably displays high-luminance images. The display device also increases the light directivity and the light output efficiency. The display device thus avoids lowering the image quality (e.g., luminance or contrast) of display images when the light emitters 4 are smaller and more power-saving in response to increased definition of display images.

With the first method for manufacturing the display device, the side walls 3c2 of the cavities 3c may be made of a conductive material. The side walls 3c2 may be placed as a stack of multiple layers on the portions of the first surface 2a other than the portions corresponding to the bottom surfaces 3c1. In this case, the side walls 3c2 of the cavities 3c may be made of a conductive material, such as a Fe—Ni alloy or a Fe—Ni—Co alloy, and may be a stack of multiple layers formed by, for example, plating. This allows the side walls 3c2 of the cavities 3c to be placed directly on the first surface 2a of the first substrate 2. This also increases flexibility in controlling, for example, the shape or the inclination angle of the side wall 3c2 of each cavity 3c. For example, each side wall 3c2 may include an inwardly curved surface or a stepped inner surface. Each layer may be thinner to easily allow the side walls 3c2 to include substantially flat inner surfaces.

With the first method for manufacturing the display device, the side walls 3c2 of the cavities 3c may be made of a semiconductive material. The side walls 3c2 may be defined by a plate including the through-holes 31 placed on the portions of the first surface 2a other than the portions corresponding to the bottom surfaces 3c1. In this case, the through-holes 31 may be formed by performing etching, such as dry etching, on a plate of a semiconductive material such as silicon. This allows high accuracy of form of the through-holes 31 defining the side walls 3c2 of the cavities 3c. For example, the etching time or the concentration of an etching agent can be controlled to control the inclination angle of the inner surface of each through-hole 31 at high accuracy. The plate including the through-holes 31 forming the side walls 3c2 of the cavities 3c may be bonded with, for example, a resin adhesive on the substrate on which the light emitters 4 are placed.

As illustrated in, for example, FIG. 11, in an embodiment of the present disclosure, a method for manufacturing the display device (also referred to as a second method for manufacturing the display device) includes processes S111, S112, and S113. The process S111 is the process of preparing the first transparent substrate and the second transparent substrate. The first transparent substrate includes the first surface including placement portions on which the light emitters are placeable. The second transparent substrate includes the second surface to face the first surface. The second surface includes portions corresponding to the bottom surfaces of the cavities to accommodate the light emitters at the positions to face the placement portions. The process S112 is the process of placing the light emitters on the placement portions. The process S113 is the process of placing the side walls of the cavities on portions of the second surface other than the portions corresponding to the bottom surfaces. The side walls are made of a conductive material or a semiconductive material and each have a height greater than or equal to three times the height of each light emitter. This structure produces the effects described below. The display device manufactured with the second method produces the same or similar effects as the various effects of the display device manufactured with the first method described above. The second method uses the first transparent substrate and the second transparent substrate, and can thus provide a transparent display device. The second method can also provide a double-sided display device that displays images on an outer surface (e.g., the front surface) of the second transparent substrate and on an outer surface (e.g., the back surface) of the first transparent substrate.

For example, the double-sided display device may include multiple light emitters including first light emitters (for display on the front surface) and second light emitters (for display on the back surface) alternate with each other. Reflectors, such as reflective layers or reflective plates, may be located directly below the first light emitters on the first transparent substrate. Reflectors may be located directly above the second light emitters on the second transparent substrate. To display images on the front surface, driving is performed to cause the first light emitters to emit light and cause the second light emitters not to emit light. To display images on the back surface, driving is performed to cause the first light emitters not to emit light and cause the second light emitters to emit light. To display images on the front and back surfaces, driving is performed to cause the first light emitters and the second light emitters to emit light.

With the second method for manufacturing the display device, the side wall of the cavity may be made of a conductive material. The side wall may be placed as a stack of multiple layers on the portion of the second surface of the second transparent substrate other than the portion corresponding to the bottom surface of the cavity. In this case, the side wall of the cavity may be made of a conductive material, such as a Fe—Ni alloy or a Fe—Ni—Co alloy, and may be a stack of multiple layers formed by, for example, plating. This allows the side wall of the cavity to be placed directly on the second surface of the second transparent substrate. This also increases flexibility in controlling, for example, the shape or the inclination angle of the side wall of the cavity. For example, the side wall may include an inwardly curved surface or a stepped inner surface. Each layer may be thinner to easily allow the side wall to include a substantially flat inner surface.

With the second method for manufacturing the display device, the side wall of the cavity may be made of a semiconductive material. The side wall may be defined by a plate including the through-hole 31 placed on the portion of the second surface other than the portion corresponding to the bottom surface. In this case, the through-hole 31 may be formed by performing etching, such as dry etching, on a plate of a semiconductive material such as silicon. This allows high accuracy of form of the through-hole 31 defining the side wall of the cavity. For example, the etching time or the concentration of an etching agent can be controlled to control the inclination angle of the inner surface of the through-hole 31 at high accuracy.

In the above embodiments, the second substrate 3 may include a transparent substrate as a body made of, for example, a glass material or a transparent resin material. The body may include the multiple through-holes 31. The second substrate 3 may include a transparent conductor layer located on the inner surfaces 31a of the through-holes 31 on the second surface 3a and on the third surface 3b.

The device with the above structure can be a transparent display including the first substrate 2 made of a transparent material such as a glass material and the second substrate 3 made of a transparent substrate. As illustrated in, for example, FIG. 10, the device may also be a double-sided display including reflectors 12, such as reflective layers or reflective plates, located in upper portions of the through-holes 31 to partially reflect light radiating from the light emitters 4 toward the back surface of the first substrate 2. In this case, as illustrated in, for example, FIG. 10, the multiple light emitters 4 may include light emitters 41 with no reflectors 12 above, and light emitters 42 with the reflectors 12 above. The light emitters 41 and 42 may alternate with each other. To display images on the front surface, driving is performed to cause the light emitters 41 to emit light and cause the light emitters 42 not to emit light. To display images on the back surface, driving is performed to cause the light emitters 41 not to emit light and cause the light emitters 42 to emit light. To display images on the front and back surfaces, driving is performed to cause the light emitters 41 and the light emitters 42 to emit light.

In one or more embodiments of the present disclosure, the display device 1 may have a structure (hereafter also referred to as a second structure) described below. In the display device 1, the cavity structure 30 may comprise the first substrate 2 and the cavity component. The first substrate 2 may include the first surface 2a including the bottom surfaces 3c1 of the cavities 3c. The cavity component may be located on the bottom surfaces 3c1 in the first surface 2a to expose the bottom surfaces 3c1. The cavity component may define the side walls 3c2 of the cavities 3c. The light emitters 4 may be located on the bottom surfaces 3c1. The cavity component may be made of a metal material or an alloy material. The cavity component with this structure effectively conducts heat from the light emitters 4 and dissipates the heat outside. The display device thus avoids lowering the light emission efficiency of the light emitters 4 and stably displays high-luminance images. The first substrate 2 may be made of, for example, a glass material. The cavity component may be made of a metal material or an alloy material. The first substrate 2 and the cavity component may have their linear expansion coefficients matching each other. This reduces the likelihood that the cavity component comes in contact with the light emitters 4 due to thermal deformation, such as thermal expansion, when the multiple light emitters 4 are more narrowly spaced from one another in response to increased definition.

The structure may include one or more cavity components. The number of cavity components may correspond to the number of light emitters 4. In a structure with multiple cavity components, the individual cavity components may be separate and independent of one another, or may be integral with one another. In the display device 1 illustrated in each of FIGS. 1 to 8 and 10, the light guide (second substrate 3) is a substantially rectangular member and includes the multiple cavity components that are integral with one another. Thus, the second substrate 3 as the light guide may also be a composite cavity component.

For the light guide including multiple cavity components that are integral with one another, adjacent cavity components may be connected using, for example, an arm- or plate-like connector or an adhesive. For the light guide including multiple cavity components that are integral with one another, multiple through-holes to be the cavities may be formed by, for example, etching or drilling in substantially a plate or a rectangular member. For the light guide including multiple cavity components that are integral with one another, multiple layers with multiple through-holes to be the cavities may be stacked on one another and joined together.

In the display device 1 with the second structure, the cavity component may have the linear expansion coefficient being 0.8 to 2 times inclusive the linear expansion coefficient of the first substrate 2 as described above. This structure produces the same or similar effects as the structure described above. The first substrate 2 may be made of a glass material. The cavity component may be made of a Fe—Ni alloy.

The display device 1 with the second structure may include the insulators 6 between the first surface 2a of the first substrate 2 and the cavity component as described above. This structure produces the same or similar effects as the structure described above.

In the display device 1 with the second structure, as descried above, the first substrate 2 may include the first electrodes and the second electrodes on the exposed portions inside the cavity component on the first surface 2a. The light emitters 4 may have the first terminals connected to the first electrodes by flip-chip connection and the second terminals connected to the second electrodes by flip-chip connection. This structure produces the same or similar effects as the structure described above.

Multiple display devices according to any of the embodiments of the present disclosure may be joined together into a composite display device (multi-display) by joining the side portions of adjacent display devices with, for example, an adhesive or screws.

### Examples

An example of a display device according to one or more embodiments of the present disclosure will now be described. Table 1 below shows the output efficiency and the directivity of light radiating outside through the through-holes 31 defining the cavities 3c for the height (height H2) of the side wall 3c2 defining each cavity 3c varied with respect to the height (height H1) of each light emitter 4. In the present example, the through-hole 31 has the shape of an inverted square truncated pyramid. The bottom surface (square) of the cavity 3c has the sides each having a length of 24 μm. The inner surface (inner side) 31a of the through-hole 31 has an inclination angle of 80°. The inner surface of the through-hole 31 has a reflectance of 90%.

The light output efficiency is expressed as a ratio normalized using the frontal luminance of light without the cavity 3c being set to 1. More specifically, the frontal luminance is obtained by measuring light at 10 cm directly above the position of the cavity 3c after radiating from the light emitter 4. The light directivity is expressed as an angle θ formed between the direction of 50% of light relative to the total light radiating outside through the cavity 3c in the direction above the cavity 3c (front direction). In other words, the angle θ is formed between the direction of light and the direction orthogonal to a virtual radiating surface of the cavity 3c. A smaller angle θ indicates a higher light directivity.

TABLE 1

| | | | Light output | |
|---|---|---|---|---|
| No. | H1 (μm) | H2 (μm) | efficiency | Light directivity (θ) |
| 1 | 10 | 10 | 1 | 80° |
| 2 | 10 | 20 | 1.9 (+0.9) | 76° (−4°) |
| 3 | 10 | 30 | 3.8 (+1.9) | 65° (−11°) |
| 4 | 10 | 40 | 4.7 (+0.9) | 60° (−5°) |
| 5 | 10 | 50 | 5.7 (+1.0) | 55° (−5°) |
| 6 | 10 | 60 | 6.8 (+1.1) | 51° (−4°) |
| 7 | 10 | 70 | 8.0 (+1.2) | 47° (−4°) |
| 8 | 10 | 80 | 9.6 (+1.6) | 45° (−2°) |
| 9 | 10 | 90 | 11.2 (+1.6) | 42° (−3°) |
| 10 | 10 | 100 | 12.5 (+1.3) | 40° (−2°) |

As shown in Table 1, the light output efficiency and the light directivity increase when the height H2 of the side wall 3c2 is greater than or equal to three times the height H1 of the light emitter 4. The values in parentheses in the light output efficiency column each indicate the difference from immediately preceding data, and the values in parentheses in the light directivity column each indicate the difference from immediately preceding data. For the height H2 being three times the height H1, the light output efficiency increases by 1.9, which is the greatest, as compared with the height H2 being twice the height H1. The light directivity improves by 11°, which is also the greatest improvement.

Although the display devices according to the embodiments of the present disclosure have been described in detail, the display devices according to the embodiments of the present disclosure are not limited to those in the above embodiments, and may be changed or varied in various manners without departing from the spirit and scope of the present disclosure. The components described in the above embodiments may be entirely or partially combined as appropriate unless any contradiction arises.

In the display device according to one or more embodiments of the present disclosure, the cavity is defined by the conductive or semiconductive side wall that can serve as the static dissipative portion to dissipate static electricity. When an insulating substrate, which easily accumulates static electricity, is used as the substrate receiving the light emitter, the substrate with the above structure accumulates less static electricity and reduces electrostatic discharge damage to the light-emitting layer in the light emitter. The light emitter may have a cathode terminal electrically connected to the side wall. In this case, the side wall with a large surface area and a large volume can serve as a stable cathode potential portion. This stabilizes the characteristics of the light emitter and facilitates control of the luminance.

The side wall of the cavity is made of a metal material or an alloy material, which is conductive, or made of a dense crystalline material such as silicon, which is semiconductive. The side wall is thus highly thermally conductive. The side wall thus effectively dissipates heat from the light emitter outside. The display device thus avoids lowering the light emission efficiency of the light emitter and displays high-luminance images.

In the display device according to one or more embodiments of the present disclosure, the side wall defining the cavity has a height greater than or equal to three times the height of the light emitter. This structure may increase the light directivity and the light output efficiency. The display device thus avoids lowering the image quality (e.g., luminance or contrast) of display images when the light emitter is smaller and more power-saving in response to increased definition of display images.

In one or more embodiments of the present disclosure, the display device manufactured with the first method includes the cavity including the side wall that can serve as at least one of the static dissipative portion or the cathode potential portion. This stabilizes the characteristics of the light emitter and facilitates control of, for example, the luminance. The side wall of the cavity has high thermal conductivity and effectively dissipates heat from the light emitter outside. The display device thus avoids lowering the light emission efficiency of the light emitter and displays high-luminance images. The display device also increases the light directivity and the light output efficiency. The display device thus avoids lowering the image quality (e.g., luminance or contrast) of display images when the light emitter is smaller and more power-saving in response to increased definition of display images.

In one or more embodiments of the present disclosure, the display device manufactured with the second method produces the same or similar effects as the various effects described above. The second method uses the first transparent substrate and the second transparent substrate, and can thus provide a transparent display device. The second method can also provide a double-sided display device that displays images on an outer surface (e.g., the front surface) of the second transparent substrate and on an outer surface (e.g., the back surface) of the first transparent substrate.

### INDUSTRIAL APPLICABILITY

The display device according to one or more embodiments of the present disclosure can be used in various electronic devices. Such electronic devices include automobile route guidance systems (car navigation systems), ship route guidance systems, aircraft route guidance systems, indicators for instruments in vehicles such as automobiles, instrument panels, smartphones, mobile phones, tablets, personal digital assistants (PDAs), video cameras, digital still cameras, electronic organizers, electronic books, electronic dictionaries, personal computers, copiers, terminals for game devices, television sets, product display tags, price display tags, programmable display devices for industrial use, car audio systems, digital audio players, facsimile machines, printers, automatic teller machines (ATMs), vending machines, medical display devices, digital display watches, smartwatches, guidance display devices installed in stations or airports, signage (digital signage) for advertisement, advertising display devices installed on the walls of buildings, and transparent display devices or double-sided display devices installed on the windows or walls of vehicles such as automobiles or trains.

### REFERENCE SIGNS

1 display device
2 first substrate
2a first surface
2aa exposed portion (element-mounting portion) of first surface
3 second substrate (light guide or cavity component)
3a second surface
3b third surface (display surface)
3c cavity
3c1 bottom surface
3c2 side wall
30 cavity structure
31 through-hole
31a inner surface
4, 4R, 4G, 4B, 41, 42 light emitter
5 light-transmissive member
51 body
52 insulating particle
6 insulator
7 first electrode (anode electrode)
8 second electrode (cathode electrode)
9 light-reflective layer
10 light-absorbing layer
11 transparent conductor layer
12 reflector

1. A display device, comprising:
a cavity structure including a display surface and a cavity in the display surface; and
a light emitter in the cavity,
wherein the cavity includes a bottom surface and a side wall, and the side wall is conductive or semiconductive, and
a height of the side wall is greater than or equal to three times a height of the light emitter.

2. The display device according to claim 1, wherein
the cavity structure comprises
a first substrate including a first surface, the first surface including the bottom surface, and
a second substrate on the first surface, the second substrate including a second surface facing the first surface, a third surface as the display surface opposite to the second surface, and a through-hole extending through the second substrate from the second surface to the third surface and forming the side wall,
the light emitter is on the bottom surface exposed through the through-hole, and
the display device further comprises an insulator between the first substrate and the second substrate.

3. The display device according to claim 2, wherein
the light emitter includes a first terminal at a first potential, and a second terminal at a second potential different from the first potential, and
the second substrate is electrically connected to the second terminal.

4. The display device according to claim 3, further comprising:
a transparent conductor layer between the first substrate and the second substrate, the transparent conductor layer being electrically connected to the second terminal,
wherein the second substrate is in contact with the transparent conductor layer.

5. The display device according to claim 2, wherein
a linear expansion coefficient of the second substrate is greater by 0.8 to 2 times inclusive than a linear expansion coefficient of the first substrate.

6. The display device according to claim 2, wherein
the through-hole includes a light-reflective inner surface.

7. The display device according to claim 2, wherein
the second substrate includes a light-absorbing layer on the third surface.

8. The display device according to claim 2, further comprising:
a light-transmissive member in the through-hole.

9. The display device according to claim 8, wherein
the light-transmissive member contains dispersed insulating particles.

10. The display device according to claim 2, wherein
the through-hole includes an opening with a section parallel to the second surface, the section gradually increasing from the second surface toward the third surface.

11. The display device according to claim 2, wherein
the second substrate is thicker than the first substrate.

12. The display device according to claim 1, wherein
the light emitter includes a vertical light-emitting diode having a terminal, a light-emitting layer on the terminal, and another terminal on the light-emitting layer.

13. The display device according to claim 1, wherein
the side wall comprises a metal material or an alloy material.

14. The display device according to claim 13, wherein
the cavity structure comprises
a substrate including a first surface, the first surface including the bottom surface of the cavity, and
a cavity component on the bottom surface in the first surface, the cavity component exposing the bottom surface, the cavity component defining the side wall of the cavity,
the light emitter is on the bottom surface, and
the cavity component comprises a metal material or an alloy material.

15. The display device according to claim 14, wherein
a linear expansion coefficient of the cavity component is greater by 0.8 to 2 times inclusive than a linear expansion coefficient of the substrate.

16. The display device according to claim 15, wherein
the substrate comprises a glass material, and
the cavity component comprises a Fe—Ni alloy.

17. The display device according to claim 14, further comprising:
an insulator between the first surface of the substrate and the cavity component.

18. The display device according to claim 17, wherein
the substrate includes a first electrode and a second electrode on a portion of the first surface exposed through the cavity component, and
the light emitter includes a first terminal connected to the first electrode by flip-chip connection, and a second terminal connected to the second electrode by flip-chip connection.

19. The display device according to claim 1, wherein
the side wall comprises an electrically conductive resin.

20. A method for manufacturing a display device, the method comprising:
preparing a substrate to include a surface having a portion corresponding to a bottom surface of a cavity to accommodate a light emitter;
placing a light emitter on the bottom surface; and
placing a side wall of the cavity on a portion of the surface other than the portion corresponding to the bottom surface, the side wall comprising a conductive material or a semiconductive material, the side wall having a height greater than or equal to three times a height of the light emitter.

21. The method according to claim 20, wherein
the placing the side wall includes placing the side wall of the cavity comprising a conductive material as a stack of multiple layers on the portion of the surface other than the portion corresponding to the bottom surface.

22. A method for manufacturing a display device, the method comprising:
preparing a first transparent substrate and a second transparent substrate, the first transparent substrate including a first surface having a placement portion on which a light emitter is placeable, the second transparent substrate including a second surface to face the first surface, the second surface including a portion corresponding to a bottom surface of a cavity to accommodate the light emitter at a position to face the placement portion;
placing the light emitter on the placement portion; and
placing a side wall of the cavity on a portion of the second surface other than the portion corresponding to the bottom surface, the side wall comprising a conductive material or a semiconductive material, the side wall having a height greater than or equal to three times a height of the light emitter.

23. The method according to claim 22, wherein
the placing the side wall includes placing the side wall of the cavity comprising a conductive material as a stack of multiple layers on the portion of the second surface other than the portion corresponding to the bottom surface.
